(19) United States
(12) Patent Application Publication
(10) Pub. No.: US 2021/0208618 A1
(43) Pub. Date: Jul. 8, 2021

(54) ON-CHIP REFERENCE CURRENT GENERATING CIRCUIT

(71) Applicant: CHANGXIN MEMORY TECHNOLOGIES, INC., Hefei (CN)

(72) Inventors: Rumin JI, Hefei (CN); Zhan YING, Hefei (CN)

(21) Appl. No.: 17/190,405

(22) Filed: Mar. 3, 2021

Related U.S. Application Data
(63) Continuation of application No. PCT/CN2020/095337, filed on Jun. 10, 2020.

(30) Foreign Application Priority Data
Oct. 16, 2019 (CN) 201910981700.6

(51) Int. Cl. G05F 3/26; H03K 19/00

(52) U.S. Cl. CPC G05F 3/262; G11C 11/4093; H03K 19/0005

(57) ABSTRACT

Embodiment provides an on-chip reference current generating circuit for supplying at least one reference current to at least one load. The on-chip reference current generating circuit includes a transistor, an operational amplifier unit, a first pull-down resistor unit, and a current mirror unit. A reference voltage is inputted to a positive input terminal of the operational amplifier unit, a negative input terminal of the operational amplifier unit is coupled to a source of the transistor, and an output terminal of the operational amplifier unit is coupled to a gate of the transistor. As a resistor unit calibrated by a ZQ calibration circuit, the first pull-down resistor unit is coupled between the source of the transistor and a ground. The current mirror unit is coupled between a drain of the transistor and a power supply voltage and is configured to output a generated current to the load for use.

### CROSS REFERENCE

This application is a continuation of PCT/CN2020/095337, filed on Jun. 10, 2020, which claims priority to Chinese Patent Application No. 201910981700.6, titled “ON-CHIP REFERENCE CURRENT GENERATING CIRCUIT” and filed on Oct. 16, 2019, the entire contents of which are incorporated herein by reference.

### TECHNICAL FIELD

The present disclosure relates to the field of integrated circuit, and more particularly, to an on-chip reference current generating circuit.

### BACKGROUND

A reference current is a current insensitive to variations of factors such as temperatures, voltages, and processes. The reference current is widely used in design of integrated circuits. For example, an oscillator circuit formed by charging and discharging a capacitor with the reference current may be used in a charge pump circuit in a DRAM. FIG. 1 is an oscillator circuit diagram. Capacitors C₁ and C₂ are charged by the reference currents I_{ch1} and I_{ch2}. When voltages across the capacitors C₁ and C₂ are charged to the same as the reference voltage V_{bg}, comparators comp₁ and comp₂ flip to set or reset a DFF. An output signal S₁ or S₂ flips and discharges the corresponding capacitor, until a clock signal is generated based on cyclic actions. Factors such as process deviation and temperature variation may cause the reference current to change, and the change of the reference current may affect charging time of the capacitor, and then affect a frequency of the clock signal, resulting in insufficient accuracy of an oscillator frequency.

FIG. 2 illustrates a reference current generating circuit frequently used in a chip. With reference to FIG. 2. by means of a clamping action of an operational amplifier amp, the voltage across a resistor R0 is also Vref, such that the current flowing through the resistor is Vref/R0. Through a current mirror composed of a transistor M12 and a transistor M13, the generated current may be outputted to other modules for use. The Vref may be obtained by dividing an internal bandgap voltage, and generally the Vref may be trimmed to obtain a reference voltage Vref having a higher precision. The Vref finally obtained is insensitive to variations of processes, voltages, and temperatures. As an on-chip resistor, the R0 generally is a polycrystalline resistor, and its resistance may vary greatly with temperature or process tolerances, which causes a consequence that the finally outputted current (i.e., the reference current) may also vary greatly with temperature or process tolerances. If the R0 is an off-chip resistor, it may occupy additional pin resources, which is disadvantageous to the miniaturization of components, and may inevitably consume a lot of space and increase production costs, and thus is not economical.

Therefore, how to enable an on-chip reference current generating circuit to output a stable reference current becomes a technology that needs to be solved urgently.

### SUMMARY

A technical problem to be solved by the present disclosure is to provide an on-chip reference current generating circuit, which can supply a stable reference current.

To solve the above problem, the present disclosure provides an on-chip reference current generating circuit for supplying at least one reference current to at least one load. The on-chip reference current generating circuit comprising a transistor, an operational amplifier unit, a first pull-down resistor unit, and a current mirror unit. A reference voltage being inputted to a positive input terminal of the operational amplifier unit, a negative input terminal of the operational amplifier unit being coupled to a source of the transistor, and an output terminal of the operational amplifier unit being coupled to a gate of the transistor. As a resistor unit calibrated by a ZQ calibration circuit, the first pull-down resistor unit is coupled between the source of the transistor and a ground. The current mirror unit is coupled between a drain of the transistor and a power supply voltage and is configured to output a generated current to the load for use.

Further, the ZQ calibration circuit has a second pull-down resistor unit and a pull-down calibration code for calibrating the second pull-down resistor unit. The first pull-down resistor unit is configured to duplicate the second pull-down resistor unit, and uses the second pull-down calibration code as a first pull-down calibration code of the first pull-down resistor unit.

Further, the first pull-down resistor unit is arranged adjacent to the second pull-down resistor unit.

Further, the reference voltage is less than 2(V_{GS}˜V_{TH}).

Further, the reference voltage is 1/100˜ 1/10 of 2(V_{GS}˜V_{TH}).

Further, the on-chip reference current generating circuit also comprising a shunt resistor unit connected in parallel with the first pull-down resistor unit. The shunt resistor unit is enabled before the first pull-down resistor unit is calibrated by the ZQ calibration circuit, and the shunt resistor unit is disabled after the first pull-down resistor unit is calibrated by the ZQ calibration circuit.

Further, the shunt resistor unit comprises at least one transistor.

Further, the source of the at least one transistor in the shunt resistor unit is grounded.

Further, the first pull-down resistor unit comprises a plurality of transistors coupled in parallel.

Further, the on-chip reference current generating circuit also comprising a bandgap voltage generator. The bandgap voltage generator is coupled to the positive input terminal of the operational amplifier unit and is configured to generate the reference voltage.

Further, the transistor is an N-type transistor.

An advantage of the present disclosure is as below. After the first pull-down resistor unit of the on-chip reference current generating circuit is calibrated by the ZQ calibration circuit, an equivalent resistance of the first pull-down resistor unit is insensitive to variations of processes, voltages, and temperatures, such that the reference current outputted from the current mirror unit may not vary greatly with the processes, the voltages, and the temperatures. Therefore, the on-chip reference current generating circuit provided by the present disclosure can supply a stable reference current.

### BRIEF DESCRIPTION OF THE DRAWINGS

FIG. 1 is a circuit diagram of an existing oscillator;

FIG. 2 is a reference current generating circuit frequently used in an existing chip;

FIG. 3 is a circuit diagram of an on-chip reference current generating circuit according to a first embodiment of the present disclosure; and

FIG. 4 is a circuit diagram of an on-chip reference current generating circuit according to a second embodiment of the present disclosure.

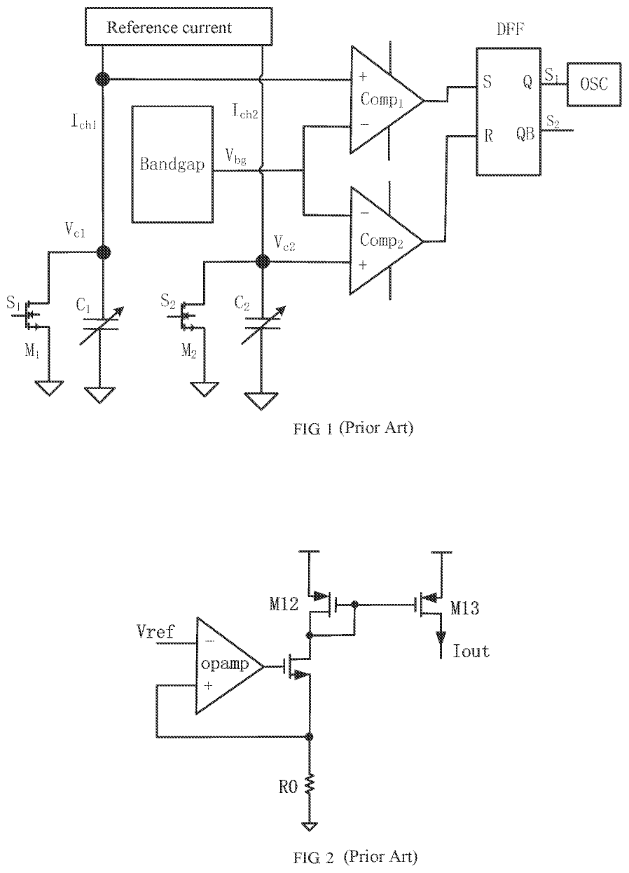

### DETAILED DESCRIPTION

Embodiments of the on-chip reference current generating circuit provided by the present disclosure are described below in detail with reference to the accompanying drawings.

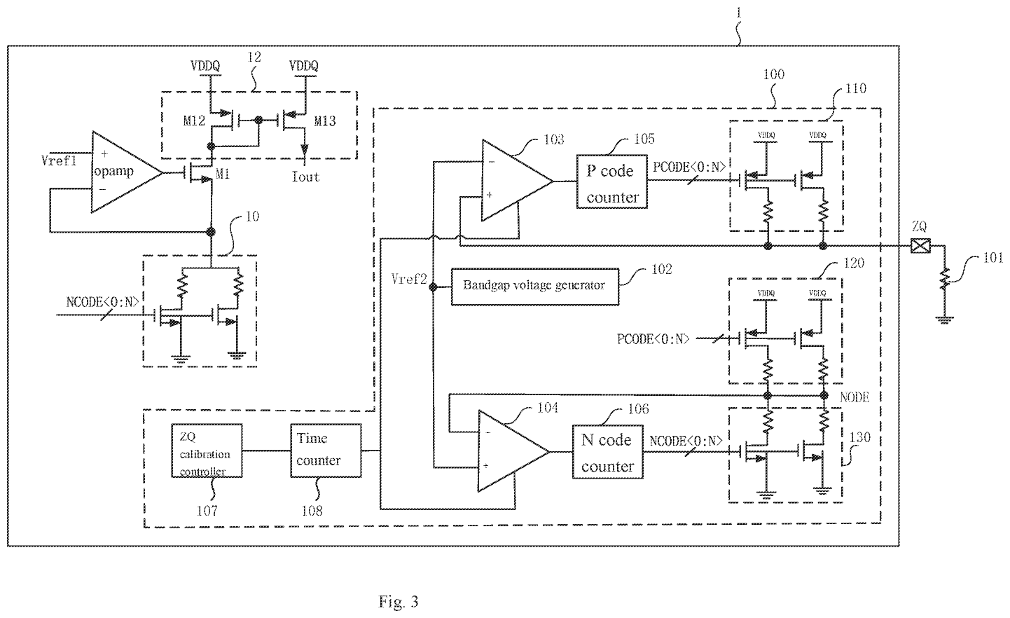

The on-chip reference current generating circuit provided by the present disclosure is arranged in a chip 1 to supply at least one reference current to at least one load. FIG. 3 is a circuit diagram of the on-chip reference current generating circuit according to a first embodiment of the present disclosure. With reference to FIG. 3, the on-chip reference current generating circuit includes a transistor M1, an operational amplifier unit opamp, a current mirror unit 12, and a first pull-down resistor unit 10. In this embodiment, the transistor M1 is an N-type transistor.

A reference voltage Vref1 is inputted to a positive input terminal of the operational amplifier unit opamp, a negative input terminal of the operational amplifier unit opamp is coupled to a source of the transistor M1, and an output terminal of the operational amplifier unit opamp is coupled to a gate of the transistor M1. In this embodiment, the reference voltage is generated by a bandgap voltage generator 102. The bandgap voltage generator 102 is coupled to the positive input terminal of the operational amplifier unit opamp, and is configured to transmit the generated reference voltage to the positive input terminal of the operational amplifier unit opamp.

The current mirror unit 12 is coupled between a drain of the transistor M1 and a power supply voltage and is configured to output a current generated by the on-chip reference current generating circuit to the load for use. In this embodiment, the current mirror unit 12 is composed of a P-type transistor M12 and a P-type transistor M13. The P-type transistor M12 has a source connected to a power supply potential, and a gate and a drain connected to the drain of the transistor M1. The P-type transistor M13 has a source connected to the power supply potential, and a gate connected to a gate and a drain of the P-type transistor M12. A drain of the P-type transistor M13 outputs a reference current. In other embodiments of the present disclosure, circuits in other forms may also be used as the current mirror unit. The current mirror unit 12 can implement replication or multiplication of a current signal. In this embodiment, the current mirror unit 12 replicates a current flowing through the first pull-down resistor unit 10, and outputs the current as the reference current.

With an equivalent resistance of R0, the first pull-down resistor unit 10 is coupled between the source of the transistor M1 and a ground. By means of a clamping action of the operational amplifier unit 11, the on-chip reference current generating circuit ensures that a voltage, whose magnitude is also Vref1, across the first pull-down resistor unit 10 is equal to the reference voltage Vref1. In this case, the current flowing through the first pull-down resistor unit 10 is Vref1/R0. The current mirror unit 12 composed of the P-type transistor M12 and the P-type transistor M13 outputs the generated current as the reference current to other modules for use.

As described in the background art, if the first pull-down resistor unit 10 is a resistor, its resistance may vary greatly with temperature or process tolerances, which causes a consequence that the finally outputted reference current may also vary greatly with temperature or process tolerances. Therefore, in order to overcome the above technical problem, in an embodiment of the present disclosure, the first pull-down resistor unit 10 is not a polycrystalline resistor, but is a resistor unit calibrated by a ZQ calibration circuit 100. For example, the first pull-down resistor unit 10 includes a plurality of transistors coupled in parallel.

A memory chip such as DDR4 generally has a ZQ calibration function. A pull-up unit and a pull-down unit are calibrated by the ZQ calibration circuit, such that equivalent resistance of the pull-up unit and the pull-down unit meet accuracy requirements. That is, the equivalent resistances of the pull-up unit and the pull-down unit calibrated are insensitive to variations of processes, voltages, and temperatures.

In one embodiment, with reference to FIG. 3, the ZQ calibration circuit 100 includes a first pull-up resistor unit 110, a second pull-up resistor unit 120, a second pull-down resistor unit 130, a bandgap voltage generator 102, a first comparator 103, a second comparator 104, a P code counter 105, and an N code counter 106. The ZQ calibration includes a pull-up calibration and a pull-down calibration.

A method for the pull-up calibration is as below. A power supply voltage VDDQ is divided by the first pull-up resistor unit 110 and a reference resistor 101 to supply a voltage to a node ZQ. The reference resistor 101 connected to a pin coupled to the node ZQ generally has a resistance of 240Ω. The first comparator 103 compares the voltage at the node ZQ with a reference voltage Vref2 outputted from the bandgap voltage generator 102, to generate an up/down signal UP/DN. The reference voltage Vre2f generally is set to a half of the supplied voltage, i.e., VDDQ/2. The P code counter 105 receives the up/down signal UP/DN, to generate a binary code PCODE<0:N> as the pull-up calibration code. The binary code PCODE<0:N> enables/disables MOS transistors coupled in parallel in the first pull-up resistor unit 110 to calibrate the resistance of the first pull-up resistor unit 110. The calibrated resistance of the first pull-up resistor unit 110 has an effect on the voltage at the node ZQ. The above operation is repeated. That is, the pull-up calibration is performed on the first pull-up resistor unit 110, such that the resistance of the first pull-up resistor unit 110 becomes equal to the resistance of the reference resistor 101. The binary code PCODE<0:N> generated during the pull-up calibration is also inputted to the second pull-up resistor unit 120, and the resistance of the second pull-up resistor unit 120 is determined.

Similar to performing the pull-up calibration, the pull-down calibration is performed. A binary code NCODE<0:N> generated by the second comparator 104 and the N code counter 106 is used as a pull-down calibration code. By using the pull-down calibration code, the voltage at the node NODE becomes equal to the reference voltage Vref2. The pull-down calibration is performed, such that the resistance of the second pull-down resistor unit 130 becomes equal to the resistance of the second pull-up resistor unit 120.

The binary codes PCODE<0:N> and NCODE<0:N> generated by the ZQ calibration are inputted to an input/output circuit to calibrate each resistor of the resistor units. In the case of a semiconductor memory device, it is determined that the binary codes PCODE<0:N> and NCODE<0:N> are connected to the resistances of the pull-up and pull-down resistors of a DQ pad. The pull-up and pull-down resistors have layouts similar to those of the above pull-up and pull-down resistor units. Further, a ZQ calibration controller 107 and a time counter 108 are employed to control the ZQ calibration.

After the first pull-up resistor unit 110 and the second pull-down resistor unit 130 are calibrated by the ZQ calibration circuit 100, their equivalent resistances meet the accuracy requirements. That is, the equivalent resistances of the first pull-up resistor unit 110 and the second pull-down resistor unit 130 calibrated are insensitive to variations of processes, voltages and temperatures.

In view of the above advantages of the ZQ calibration circuit, the on-chip reference current generating circuit provided by the present disclosure uses the pull-down calibration code NCODE<0:N> of the ZQ calibration circuit, and duplicates the second pull-down resistor unit 130 of the ZQ calibration circuit as the first pull-down resistor unit 10 of the on-chip reference current generating circuit provided by the present disclosure. In this case, the first pull-down resistor unit 10 is determined as a resistor unit calibrated by the ZQ calibration circuit, and the equivalent resistance of the first pull-down resistor unit 10 is insensitive to variations of processes, voltages and temperatures. In this embodiment, the first pull-down resistor unit 10 and the second pull-down resistor unit 130 are strictly matched in layout, placement and routing. MOS transistors corresponding to the first pull-down resistor unit 10 and the second pull-down resistor unit 130 adopt the same size and arrangement direction. Furthermore, the first pull-down resistor unit 10 and the second pull-down resistor unit 130 adopt the same control signal, i.e., the pull-down calibration code NCODE<0:N>.

In one embodiment, in the layout and placement, the first pull-down resistor unit 10 is arranged adjacent to the second pull-down resistor unit 130 to prevent other influence factors from causing different calibrations by the ZQ calibration circuit on the first pull-down resistor unit 10 and the second pull-down resistor unit 130, thereby reducing the sensitivity of the equivalent resistance of the first pull-down resistor unit 10 to the variations of processes, voltages and temperatures.

Further, to ensure the first pull-down resistor unit 10 to be closer to a real resistance, the value of the reference voltage Vref1 of the on-chip reference current generating circuit provided by the present disclosure is not allowed to be too large. In one embodiment, the value of the reference voltage Vref1 of the on-chip reference current generating circuit provided by the present disclosure is less than 2(V_{GS}−V_{TH}), such that the MOS transistor in the first pull-down resistor unit 10 is in a triode region, where V_{GS} represents a gate-source voltage of the MOS transistor in the first pull-down resistor unit 10, and V_{TH} represents a breakdown voltage of the MOS transistor in the first pull-down resistor unit 10. In another embodiment, the value of the reference voltage Vref1 is much smaller than 2(V_{GS}−V_{TH}). For example, the value of the reference voltage Vref1 is 1/100˜ 1/10 of 2(V_{GS}−V_{TH}), such that the MOS transistor in the first pull-down resistor unit 10 is in a deep triode region, and the first pull-down resistor unit 10 is closer to the real resistance.

In the on-chip reference current generating circuit provided by the present disclosure, a traditional on-chip resistor is replaced with the first pull-down resistor unit 10 calibrated by the ZQ calibration circuit. The equivalent resistance of the first pull-down resistor unit 10 calibrated by the ZQ calibration circuit may not vary greatly with temperature or process tolerances, and the reference current outputted from the current mirror unit 12 may not vary greatly with the temperature or process tolerances. Therefore, the on-chip reference current generating circuit provided by the present disclosure can supply a stable reference current.

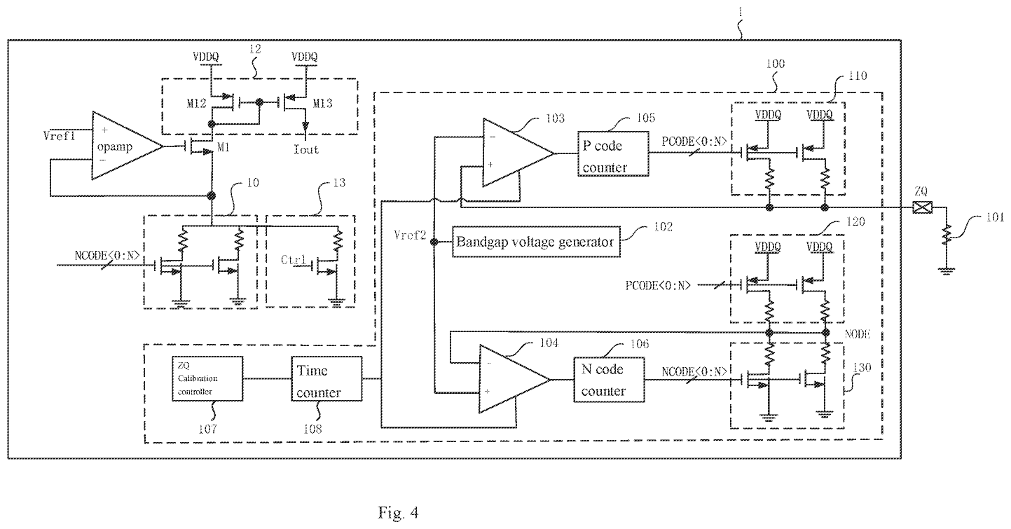

In addition, it is found that when the ZQ calibration circuit is initialized, the first pull-down resistor unit 10 is completely disabled, and thus no current can be generated, which may have a negative effect on the generation of the reference current. To prevent the occurrence of the above problem, the present disclosure also provides a second embodiment of the on-chip reference current generating circuit. FIG. 4 is a circuit diagram of the on-chip reference current generating circuit according to the second embodiment of the present disclosure. With reference to FIG. 4, to prevent the negative effect on the generation of the reference current caused by failed generation of the current because the first pull-down resistor unit 10 is completely disabled when the ZQ calibration circuit is initialized, the on-chip reference current generating circuit further includes a shunt resistor unit 13 connected in parallel with the first pull-down resistor unit 10. The shunt resistor unit 13 is enabled before the first pull-down resistor unit 10 is calibrated by the ZQ calibration circuit 100, to ensure that there is still a current path. The shunt resistor unit 13 is disabled after the first pull-down resistor unit 10 is calibrated by the ZQ calibration circuit 100, which does not have a negative effect on the normal operation of the reference current generating circuit.

In this embodiment, the shunt resistor unit 13 includes at least one transistor. In this embodiment, the transistor is an NMOS transistor. The source of the transistor is grounded, and a control signal Ctrl is inputted to the gate of the transistor. When the transistor of the first pull-down resistor unit 10 is not enabled, the control signal Ctrl is high, the transistor is enabled, and the shunt resistor unit 13 is grounded, to ensure that there is still a current path in the on-chip reference current generating circuit. The shunt resistor unit 13 is disabled after the ZQ calibration function works, which does not have a negative effect on the normal operation of the reference current generating circuit. The control signal Ctrl may be generated by a controller of an integrated circuit.

What is claimed is:

1. An on-chip reference current generating circuit for supplying at least one reference current to at least one load, the on-chip reference current generating circuit comprising:
a transistor;
an operational amplifier unit, a reference voltage being inputted to a positive input terminal of the operational amplifier unit, a negative input terminal of the operational amplifier unit being coupled to a source of the transistor, and an output terminal of the operational amplifier unit being coupled to a gate of the transistor;
a first pull-down resistor unit coupled between the source of the transistor and a ground, the first pull-down resistor unit being a resistor unit calibrated by a ZQ calibration circuit; and
a current mirror unit coupled between a drain of the transistor and a power supply voltage, wherein the current mirror unit is configured to output a generated current to the load for use.

2. The on-chip reference current generating circuit according to claim 1, wherein the ZQ calibration circuit has a second pull-down resistor unit and a second pull-down calibration code configured for calibrating the second pull-down resistor unit, wherein
the first pull-down resistor unit is configured to duplicate the second pull-down resistor unit, and use the second pull-down calibration code as a first pull-down calibration code of the first pull-down resistor unit.

3. The on-chip reference current generating circuit according to claim 2, wherein the first pull-down resistor unit is arranged adjacent to the second pull-down resistor unit.

4. The on-chip reference current generating circuit according to claim 1, wherein the reference voltage is less than 2(V_{GS}−V_{TH}).

5. The on-chip reference current generating circuit according to claim 4, wherein the reference voltage is 1/100˜ 1/10 of 2(V_{GS}−V_{TH}).

6. The on-chip reference current generating circuit according to claim 1, further comprising a shunt resistor unit connected in parallel with the first pull-down resistor unit, wherein the shunt resistor unit is enabled before the first pull-down resistor unit is calibrated by the ZQ calibration circuit, and the shunt resistor unit is disabled after the first pull-down resistor unit is calibrated by the ZQ calibration circuit.

7. The on-chip reference current generating circuit according to claim 6, wherein the shunt resistor unit comprises at least one transistor.

8. The on-chip reference current generating circuit according to claim 7, wherein the source of the at least one transistor in the shunt resistor unit is grounded.

9. The on-chip reference current generating circuit according to claim 1, wherein the first pull-down resistor unit comprises a plurality of transistors coupled in parallel.

10. The on-chip reference current generating circuit according to claim 1, further comprising a bandgap voltage generator, wherein the bandgap voltage generator is coupled to the positive input terminal of the operational amplifier unit and is configured to generate the reference voltage.

11. The on-chip reference current generating circuit according to claim 1, wherein the transistor is an N-type transistor.

12. A chip, comprising an on-chip reference current generating circuit for supplying at least one reference current to at least one load, wherein the on-chip reference current generating circuit comprises:
a transistor;
an operational amplifier unit, a reference voltage being inputted to a positive input terminal of the operational amplifier unit, a negative input terminal of the operational amplifier unit being coupled to a source of the transistor, and an output terminal of the operational amplifier unit being coupled to a gate of the transistor;
a first pull-down resistor unit coupled between the source of the transistor and a ground, the first pull-down resistor unit being a resistor unit calibrated by a ZQ calibration circuit; and
a current mirror unit coupled between a drain of the transistor and a power supply voltage, wherein the current mirror unit is configured to output a generated current to the load for use.

13. The chip according to claim 12, wherein the ZQ calibration circuit has a second pull-down resistor unit and a second pull-down calibration code configured for calibrating the second pull-down resistor unit, wherein
the first pull-down resistor unit is configured to duplicate the second pull-down resistor unit, and use the second pull-down calibration code as a first pull-down calibration code of the first pull-down resistor unit.

14. The chip according to claim 13, wherein the first pull-down resistor unit is arranged adjacent to the second pull-down resistor unit.

15. The chip according to claim 12, wherein the reference voltage is less than 2(V_{GS}−V_{TH}).

16. The chip according to claim 12, wherein the on-chip reference current generating circuit further comprises a shunt resistor unit connected in parallel with the first pull-down resistor unit, wherein the shunt resistor unit is enabled before the first pull-down resistor unit is calibrated by the ZQ calibration circuit, and the shunt resistor unit is disabled after the first pull-down resistor unit is calibrated by the ZQ calibration circuit.

17. The chip according to claim 16, wherein the shunt resistor unit comprises at least one transistor.

18. The chip according to claim 17, wherein the source of the at least one transistor in the shunt resistor unit is grounded.

19. The chip according to claim 12, wherein the first pull-down resistor unit comprises a plurality of transistors coupled in parallel.

20. The chip according to claim 12, wherein the on-chip reference current generating circuit further comprises a bandgap voltage generator, wherein the bandgap voltage generator is coupled to the positive input terminal of the operational amplifier unit and is configured to generate the reference voltage.
